(19) United States
(12) Patent Application Publication
(10) Pub. No.: US 2013/0180560 A1
(43) Pub. Date: Jul. 18, 2013

(54) NANOSCALE, ULTRA-THIN FILMS FOR EXCELLENT THERMOELECTRIC FIGURE OF MERIT

(71) Applicant: RESEARCH TRIANGLE INSTITUTE, Research Triangle Park, NC (US)

(72) Inventors: Rama VENKATASUBRAMANIAN, Cary, NC (US); Phillip BARLETTA, Cary, NC (US); Bryson QUILLIAMS, Durham, NC (US); Geza DEZSI, Durham, NC (US); Thomas COLPITTS, Durham, NC (US); Gary BULMAN, Cary, NC (US); Judy STUART, Apex, NC (US)

(73) Assignee: RESEARCH TRIANGLE INSTITUTE, Research Triangle Park, NC (US)

(21) Appl. No.: 13/725,046

(22) Filed: Dec. 21, 2012

Related U.S. Application Data
(63) Continuation of application No. PCT/US2012/065829, filed on Nov. 19, 2012.
(60) Provisional application No. 61/562,868, filed on Nov. 22, 2011.

(51) Int. Cl. H01L 35/28; H01L 35/18; H01L 35/22; H01L 35/16

(52) U.S. Cl. CPC H01L 35/28; H01L 35/16; H01L 35/18; H01L 35/22
USPC 136/201; 136/200; 136/238; 136/204; 136/240; 136/236.1

(57) ABSTRACT

A thermoelectric structure including a thermoelectric material having a thickness less than 50 nm and a semi-insulating material in electrical contact with the thermoelectric material. The thermoelectric material and the semi-insulating materials have an equilibrium Fermi level, across a junction between the thermoelectric material and the semi-insulating material, which exists in a conduction band or a valence band of the thermoelectric material. The thermoelectric structure is for thermoelectric cooling and thermoelectric power generation.

This application is a continuation application of PCT Application No. PCT/US2012/65829, filed Nov. 19, 2012. This application claims priority under 35 U.S.C. 119(e) of U.S. Ser. No. 61/562,868, filed Nov. 22, 2011, the entire contents of each are incorporated herein by reference.

### BACKGROUND OF THE INVENTION

1. Field of the Invention

The invention relates generally to the formulation and fabrication of materials, components or elements having high performance thermoelectric properties.

2. Discussion of Background

The performance of thermoelectric devices depends on the figure-of-merit (ZT) of the material, (α²T/ρK_{T}), where α, T, ρ, K_{T} are the Seebeck coefficient, absolute temperature, electrical resistivity, and total thermal conductivity, respectively. Commercial thermoelectric devices utilize alloys, typically p-BiₓSb₂₋ₓTe_{3-y}Se_{y} (x˜0.5, y˜0.12) and n-Bi₂(Se_{y}Te_{1-y})₃ (y˜0.05) for the 200K-400K temperature range. For certain alloys, the lattice thermal conductivity (K_{L}) can be reduced more strongly than carrier mobility (μ) leading to enhanced ZT². The highest ZT in a conventional alloy bulk thermoelectric material at 300K is around ˜1 for both p-type and n-type materials.

A significant enhancement in ZT in nanoscale materials, with p-type Bi₂Te₃/Sb₂Te₃ superlattices, of about 2.4 at 300K, has been achieved through a strong reduction in K_{L} (0.25 W/m-K compared to ˜1.0 W/m-K in conventional alloys of Bi₂Te₃ materials) in superlattices, along with a mini-band electronic transport across the superlattice interfaces which apparently leads to minimal anisotropy of carrier transport. These phenomena demonstrated in p-type Bi₂Te₃/Sb₂Te₃ superlattice thin-films, arising from phonon-blocking, electron-transmitting structures, have been replicated in nano-bulk BiₓSb₂₋ₓTe₃ materials produced by several methods as well as in other low-dimensional materials.

Descriptions of this and related work are found in the following references, incorporated herein by reference in their entirety:
1. H. J. Goldsmid, Thermoelctric Refrigeration (Plenum, New York, 1964).
2. A. F. Ioffe, Semiconductor Thermoelements and Thermoelectric Cooling (Infoserach, London, 1957).
3. R. Venkatasubramanian, E. Siivola, T. Colpitts & B. O'Quinn, Nature 413, 597 (2001).
4. R. Venkatasubramanian, in Recent Trends in Thermoelectric Materials Research III (ed. Tritt, T. M.) Ch. 4 (Academic, San Diego, 2001).
5. B. Poudel, Q. Hao, Y. Ma, Y. C. Lan, A. Minnich, B. Yu B, X. A. Yan, D. Z. Wang, A. Muto, D. Vashaee, X. Y. Chen, J. M. Liu, M. S. Dresselhaus, G. Chen and Z. F. Ren, Science 320, 634 (2008).
6. W. Xie, X. Tang, Y. Yan, Q. Zhang and T. M. Tritt, Appl. Phys. Lett. 94, 102111 (2009).
7. Y. Q. Cao, X. B. Zhao, T. J. Zhu, X. B. Zhang and J. P. Tu, Appl. Phys. Lett. 92, 143106 (2008).
8. X. W. Wang, H. Lee, Y. C. Lan, G. H. Zhu, G. Joshi, D. Z. Wang, J. Yang, A. J. Muto, M. Y. Tang, J. Klatsky, S. Song, M. S. Dresselhaus, G. Chen and Z. F. Ren, Appl. Phys. Lett. 93, 193121 (2008).
9. A. Hochbaum, R. K. Chen, R. D. Delgado, W. J. Liang, E. C. Garnett, M. Najarian, A. Majumdar and P. D. Yang, Nature 451, 163 (2008); A. Boukai, Y. Bunimovich, T. K. Jamil, J. K. Yu, W. A. Goddard and J. R. Heath, Nature 451, 168 (2008).
10. L. D. Hicks and M. S. Dresselhaus, Phys. Rev. B 47, 12727 (1993).
11. G. Mahan and H. Lyon, J. Appl. Phys. 76, 1899 (1994).
12. H. Ohta, S. Kim, Y. Mune, T. Mizoguchi, K. Nomura, S. Ohta, T. Nomura, Y. Nakanishi, Y. Ikuhara, m. Hirano, H. Hosono, and K. Koumoto, Nature Materials 6, 129 (2007).
13. P. Ghaemi, R. S. K. Mong and J. E. Moore, Phys. Rev. Lett. 105, 166603 (2010).
14. F. Zahid and R. Lake, Appl. Phys. Lett. 97, 212102 (2010).
15. H. Scherrer and S. Scherrer, in CRC Handbook of Thermoelectrics (ed. Rowe, D. M.) 211-237 (CRC Press, Boca Raton, Fla., 1995).
16. V. Goyal, D. Teweldebrhan and A. A. Balandin, Appl. Phys. Lett. 97, 133117 (2010).
17. M. G. Vavilov and A. D. Stone, Phys. Rev. B 72, 205107 (2005).
18. I. Chowdhury, R. Prasher, K. Lofgreen, G. Chrysler, S. Narasimhan, R. Mahajan, D. Koester, R. Alley and R. Venkatasubramanian, Nature Nanotechnology 4, 235 (2009).
19. R. Venkatasubramanian, T. Colpitts, and E. Watko, I Cryst. Growth 170, 817 (1997).
20. R. Venkatasubramanian, T. Colpitts, B. C. O'Quinn, S. Liu, N. El-Masry, and M. Lamvik, Appl. Phys. Lett. 75, 1104 (1999).
21. B. D. Cullity, Elements of X-ray Diffraction, Addison-Wesley Publishing Company (1978).
22. H. Cui, I. Bhat, B. O'Quinn and R. Venkatasubramanian, J. Electronic Materials 30, 1376 (2001); H. Cui, I. B. Bhat and R. Venkatasubramanian, J. Electronic Materials 28, 1111 (1999).
23. L. J. van der Pauw, Phillips Tech. Rev. 20, 220 (1959).
24. R. Venkatasubramanian (RTI) and Y. Chen (Purdue) et al., To be published.
25. Y. Y. Li et. al., Adv. Mater. 22, 4002 (2010).
26. D. G. Cahill, M. Katiyar and J. R. Abelson, Phys. Rev. B 50, 6077 (1994).
27. S. M. Lee, D. G. Cahill and R. Venkatasubramanian, Appl. Phys. Lett. 70, 2957 (1997); R. Venkatasubramanian, Phys. Rev. B 61, 3091 (2000).
28. X. W. Zhou, R. E. Jones, and S. Aubry, Phys. Rev. B 81, 073304 (2010).
29. Y. Wang, C. Liebig, X. Xu, and R. Venkatasubramanian, Appl. Phys. Lett. 97, 083103 (2010).
30. W. E. Beis, R. J. Radtke, H. Ehrenreich and E. Runge, Phys. Rev. B 65, 085208 (2002).
31. R. T. Delves, A. E. Bowley, D. W. Hazelden and H. J. Goldsmid, Proc. Phys. Soc. 78, 838 (1961).
32. B. Seradjeh, J. E. Moore and M. Franz, Phys. Rev. Lett. 103, 066402 (2009).
33. V. Ginzburg, Reviews of Modern Physics 76, 981 (2004).

### SUMMARY OF THE INVENTION

According to one embodiment of the invention, there is provided a thermoelectric structure including a thermoelectric material having a thickness less than 50 nm and a semi-insulating material in electrical and mechanical contact with the thermoelectric material. The thermoelectric material and the semi-insulating materials have an equilibrium Fermi level, across a junction between the thermoelectric material and the semi-insulating material, which exists in a conduction band or a valence band of the thermoelectric material.

According to another embodiment of the invention, there is provided a method for generating thermoelectric power which includes: providing a heat source and a heat sink at a lower temperature than the heat source, connecting at least one of a n-type thermoelectric material and a p-type thermoelectric material, each having a thickness less than 50 nm and disposed on a first semi-insulating material, between the heat source and the heat sink, and separately collecting carrier flow from the n-type thermoelectric material and carrier flow from the p-type material to form a thermoelectric potential related to a temperature differential between the heat source and the heat sink.

According to another embodiment of the invention, there is provided a method for thermoelectric cooling which includes: connecting at least one of a n-type thermoelectric material and a p-type thermoelectric material, each having a thickness less than 50 nm and disposed on a first semi-insulating material, to a temperature-controllable stage, and electrically flowing current through the n-type thermoelectric material, the first temperature-controllable stage, and the p-type material to cool the first temperature-controllable stage relative to the second temperature-controllable stage.

It is to be understood that both the foregoing general description of the invention and the following detailed description are exemplary, but are not restrictive of the invention.

### BRIEF DESCRIPTION OF THE FIGURES

A more complete appreciation of the invention and many of the attendant advantages thereof will be readily obtained as the same becomes better understood by reference to the following detailed description when considered in connection with the accompanying drawings, wherein:

FIG. 1(a) is a depiction of X-ray diffraction data (2θ versus Intensity) of a number of Bi₂Te₃ films grown on GaAs;

FIG. 1(b) is a schematic depicting the FWHM of the dominant Bi₂Te₃ (0,0,15) X-ray reflection plotted as a function of 1/thickness;

FIG. 2(a) is a schematic of one embodiment of a thermoelectric device structure showing a hetero-structure band diagram associated with 1) an n-type Bi₂Te₃ film, 2) a semi-insulating GaAs (E_{f} at mid-gap) substrate on one side, and 3) free space on other side;

FIG. 2(b) is a schematic of a more general depiction of the Fermi levels and band energies of this invention;

FIG. 3 is a depiction of the measured in-plane electrical resistivity (at 300K) of the ultra-thin Bi₂Te₃ films grown on semi-insulating GaAs, where resistivity (1/σ) is plotted as a function of film thickness;

FIG. 4(a) is a schematic of in-plane Seebeck measurement system;

FIG. 4(b) is a depiction of the measured absolute values of the in-plane Seebeck coefficient (a), at ˜300K of the ultra-thin n-Bi₂Te₃ films grown on semi-insulating GaAs, plotted as a function of film thickness;

FIG. 5 is a depiction of the measured in-plane thermoelectric power factor (α²σ), at ˜300K, as a function of thickness of the Bi₂Te₃-film thickness;

FIG. 6(a) is a cross-sectional schematic of a thermal conductivity measurement structure used for a 3ω-measurement;

FIG. 6(b) is a depiction of ΔT vs ln (2ω) for the GaAs/SiN reference and the GaAs/Bi₂Te₃(58 nm)/SiN structure;

FIG. 6(c) is a depiction of ΔT vs ln(2ω) for the GaAs/SiN reference and the GaAs/Bi₂Te₃(6 nm)/SiN structure;

FIG. 7 is a graph showing thermal conductivity as a function of thickness of the ultra-thin Bi₂Te₃ films measured by the 3-ω method;

FIG. 8(a) is a depiction of the anisotropy of electrical conductivity, or the factor by which cross-plane electrical conductivity is lowered, as a function of in-plane electrical conductivity in n-type Bi₂Te₃ denoted as S₁₁;

FIG. 8(b) is a depiction of the anisotropy of electrical conductivity, or the factor by which cross-plane electrical conductivity is lowered, as a function of thickness of the ultra-thin Bi₂Te₃ films;

FIG. 9 is a depiction of the estimated ZT as a function of thickness of the ultra-thin Bi₂Te₃ films;

FIG. 10 is a depiction of the effective Lorentz Parameter from the measured thermal conductivity and the estimated electrical conductivity, for the two anisotropy models;

FIG. 11 is a schematic of thermoelectric generator according to one embodiment of the invention;

FIG. 12 is a schematic of a thermoelectric cooler according to one embodiment of the invention;

FIG. 13(a) is a schematic showing a sequence according to this invention for device fabrication with ultra-thin Bi₂Te₃ films;

FIG. 13(b) is a schematic of a process sequence to attach a processed device structure to a suitable, low thermal conductivity, mechanically rigid support structure;

FIG. 14 is a schematic showing a cooling device of this invention using the ultra-thin Bi₂Te₃ films and structures of the invention; and

FIG. 15 is a schematic of a thin-film planar device structure of this invention for heat-to-electric power conversion.

### DETAILED DESCRIPTION OF THE INVENTION

While remarkable progress in using lattice thermal conductivity reduction to enhance ZT has been continuing, the approach of quantum-confinement to enhance the density of states in a 2-d quantized layer, and hence its Seebeck coefficient, has been limited. This limited success is from the requirement of adjoining potential barrier layers that provide quantum confinement, which leads to parasitic thermal conductivity thereby lowering the overall achievable ZT. Even though considerable research has been done with the quantum-confinement effects, results which show a definitive confirmation of increased power factor and enhanced three-dimensional ZT in a thermoelectric materials system such as in Bi₂Te₃, have not been demonstrated.

In addition to the quantum-confinement effects in nanoscale Bi₂Te₃, there have been exciting recent theoretical predictions of topological insulator (TI) formation and its implication for thermoelectric effects in Bi₂Te₃. Here, depending on the location of the Fermi-level, the theoretical estimates suggest that the power factor can be increased by a factor of ˜7, over that obtainable in bulk Bi₂Te₃, at low (˜100K) temperatures. Also recently, an atomic quintuple Bi₂Te₃ film of only about 7.48-Å-thick has been theoretically predicted to have a factor of 10 increase in thermoelectric power factor over that obtainable in bulk Bi-2Te3 and its alloys at 300K which are typically around 45 μW/K²-cm. However, recent experimental work in exfoliated stacked Bi₂Te₃ films has actually shown a reduced power factor of 6.1 βW/K²-cm, based on a Seebeck coefficient of 247 βV/K and electrical resistivity of 10⁻⁴ Ohm-m or 10⁻² Ohm-cm.

Detailed below are experimental thermoelectric characteristics of semi-insulating GaAs/ultra-thin-Bi₂Te₃/air heterostructures realized by the inventors. These novel structures provide a pathway to realize the very large ZT (as much as 400) and also to allow thermoelectric devices to be made with these materials with large enhancements in ZT.

In this invention, ultra-high electrical conduction in the plane of the ultra-thin Bi₂Te₃ films, have been observed by the inventors. Surprisingly, a significant Seebeck coefficient has been observed in these films leading to a significant enhancement in power factor, hitherto, not realized. Extremely low thermal conductivity of these ultra-thin Bi₂Te₃ films have been observed using the 3-ω) method in the cross-plane direction to the film, suggesting potential deviation from the Wiedemann-Franz law in mesoscopic ultra-high-conductivity Bi₂Te₃ structures.

The large enhancement in power factor with the ultra-low thermal conductivities could potentially lead to a thermoelectric figure of merit ZT in the range of 14 to 28 at 300K, when corrected for potential anisotropy of thermal conductivities, to over 400 at 300K, if anisotropies do not exist in these novel electronic conduction systems of the invention involving ultra-thin N-type Bi₂Te₃ thin films. In one embodiment of the invention, ultra-thin Bi₂Te₃ films with large ZT adopted to a device format without loss of much of the intrinsic ZT due to electrical contact and thermal interface parasitics will have a significant impact on thermoelectric devices including but not limited to solid state direct energy conversion applications like electronics chip-cooling to low-grade waste-heat harvesting

In one embodiment of the invention, thermoelectric characteristics of ultra-thin Bi₂Te₃ films in the range of 2 nm to 58 nm grown on electrically-insulating GaAs substrates form a novel structure with previously unrealized thermoelectric properties. Films at these thinner dimensions show ultra-high electrical conductivity, yet show sufficiently large Seebeck coefficients leading to a major enhancement in power factor that is almost seven (7) times larger than those in typical bulk Bi₂Te₃ materials. In addition, the Bi₂Te₃ films at the thinner dimensions, show ultra-low thermal conductivities as measured by 3-w method.

Without limiting this invention, these unusual properties of ultra-thin-Bi₂Te₃ films arise in theory from a combination of quantum-confinement, topological insulator and electron-condensate-like effects, all aided by the unusual interface between Bi₂Te₃ and semi-insulating GaAs. These results provide pathways to dramatically enhance the thermoelectric figure of merit (ZT) near 300K. The large enhancement in power factor with the ultra-low thermal conductivities is potentially capable of ZT in the range of 14 to 28 at 300K, when corrected for potential anisotropy of thermal conductivities, to as much as 400 if anisotropies do not exist in these novel electronic conduction systems of the thin n-type Bi₂Te₃ films.

### Materials Deposition and Heterostructures

In one embodiment of the invention, ultra-thin-Bi₂Te₃ layers are grown on single crystal GaAs substrates by MOCVD. In this approach, organometallic sources such as for example di-iso-propyl-tellurium and trimethylbismuth can be used as tellurium and bismuth sources, respectively. Thin-Bi₂Te₃ layers can be substituted by similar compounds like BiₓSb₂₋ₓTe₃₋ₓBi₂Te₃₋ₓSeₓ, etc. The Sb-containing materials can be grown by MOCVD with tris-dimethyl-amino antimony (for example) and the Se-containing materials can be grown in MOCVD by using hydrogen selenide as a source gas. The growth temperatures can be around 200 to 400° C. and can take advantage of Low-temperature Chemical Vapor Deposition and Etching Apparatus and Method (see for example U.S. Pat. No. 6,071,351, the entire contents of which are incorporated herein by reference). The growth conditions during MOCVD are adjusted to produce stoichiometric films and N-type conduction, through control of flow rates of Bi and Te organometallic precursors. In one embodiment, the growth temperature is lowered sufficiently with the MOCVD method to obtain a deposition rate of ˜0.4 Å/sec, to obtain control of the deposition for the all the thicknesses reported here. See above-referenced U.S. Pat. No. 6,071,351 for example although other growth methods would also be applicable. In addition to MOCVD, MBE grown Bi₂Te₃, Sb₂Te₃, Bi₂₋ₓSbₓTe₃, Bi₂Te₃₋ₓSeₓ compounds can also be deposited on semi-insulating GaAs and related semi-insulating substrates like InP using Bi, Sb, Te, and Se elements in hot-cells. Also, low-pressure evaporation (at background pressures of 10⁻⁴ to 10⁻⁸ Torr) using Bi₂Te₃, Sb₂Te₃, Bi₂₋ₓSbₓTe₃, Bi₂Te₃₋ₓSeₓ bulk materials could be used for direct evaporation of the films of 2 to 50 nm directly onto semi-insulating GaAs and related substrates. The MBE deposition and low-pressure evaporation process could be carried out with semi-insulating GaAs and related substrates at 200 to 400° C.

In another embodiment of the invention, ultra-thin-Bi₂Te₃ layers are grown by techniques other than MOCVD, such as for example solid-source molecular beam epitaxy with bismuth and tellurium source. In this embodiment, Bi and Te are evaporated from two independently controlled molybdenum boats, in order to achieve Bi₂Te₃ films. A similar procedure can be used for Sb₂Te₃ deposition by evaporation from two independent Sb and Te sources. A mixture of these solid sources can be used for the deposition of alloys of Bi₂Te₃ and Sb₂Te₃.

In one embodiment, the Bi₂Te₃ material can be grown on semi-insulating substrates made of GaAs, InP or CdTe, MgO, etc. In one embodiment, the substrates can be of <100>, <111> and other such crystalline orientations with or without miscuts. In one embodiment, the underlying semi-insulating substrate is retained for the devices. In another embodiment, the underlying semi-insulating substrate is thinned or removed completely. In another embodiment, the underlying semi-insulating substrate after being thinned or removed is transferred onto a low thermal conductivity material such as for example kapton.

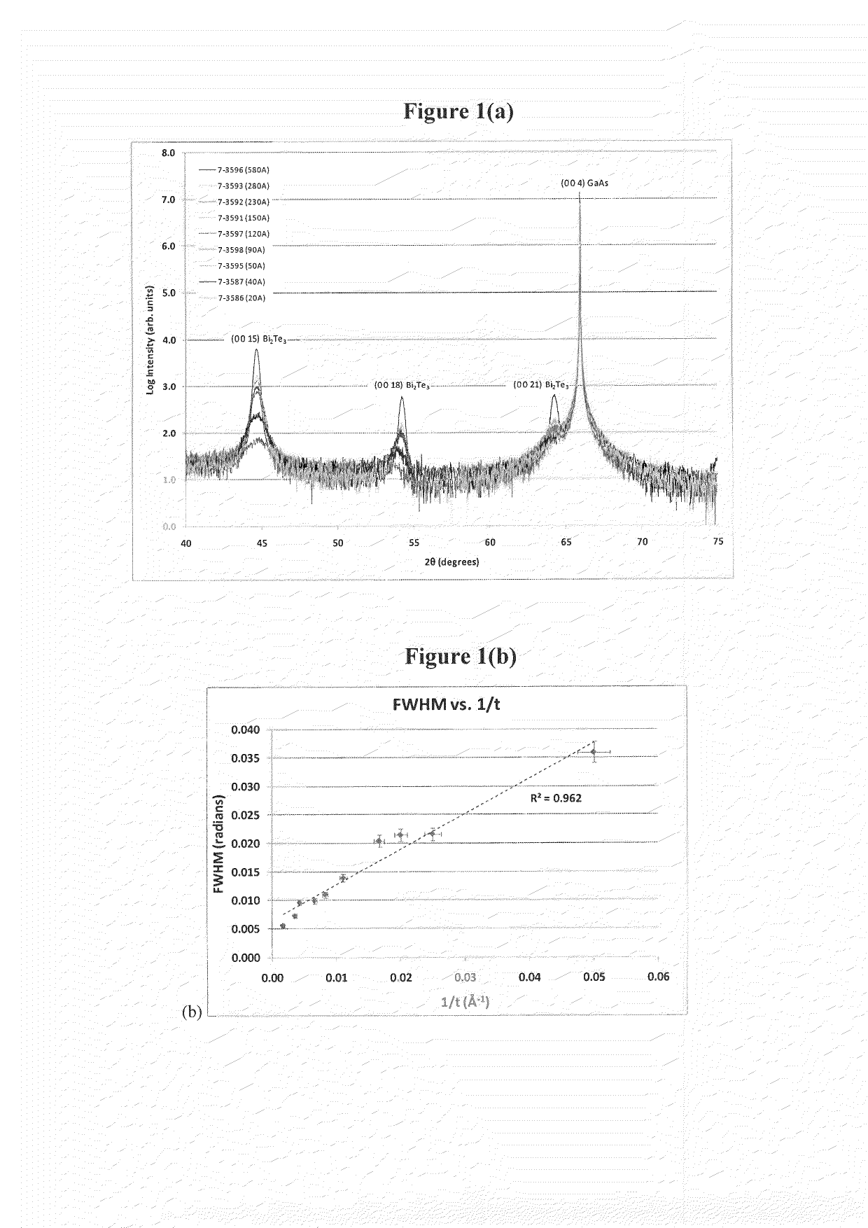

FIG. 1(a) is plot of X-ray diffraction (2θ versus Intensity) data of 2 to 58 nm Bi₂Te₃ films grown on GaAs. FIG. 1(b) is a plot showing the trend of FWHM of the dominant Bi₂Te₃ (0,0,15) reflection plotted as a function of 1/thickness, consistent with Scherrer relationship for nanoscale structures. This data represents an X-ray diffraction (XRD) study of the films as a function of thickness between 2 nm to 58 nm ins (shown in FIG. 1a, 1b), which shows that films as thin as 2 nm have classical XRD reflections associated with a c-axis crystalline Bi₂Te₃. Thinner films such as a 1 nm Bi₂Te₃ film on a GaAs substrate also showed excellent single crystallinity and all the necessary Bragg reflections, in spite of consisting of being only 5 “d-spacings” (˜5×0.2 nm). The plot of FWHM of the (0,0,15) peak as a function of inverse of film thickness (FIG. 1 b), and the linearity especially at smaller thicknesses, is consistent with the expected Scherer relationship. The confirmed film thicknesses in the range of <3 nm has been confirmed using ellipsometry methodology.

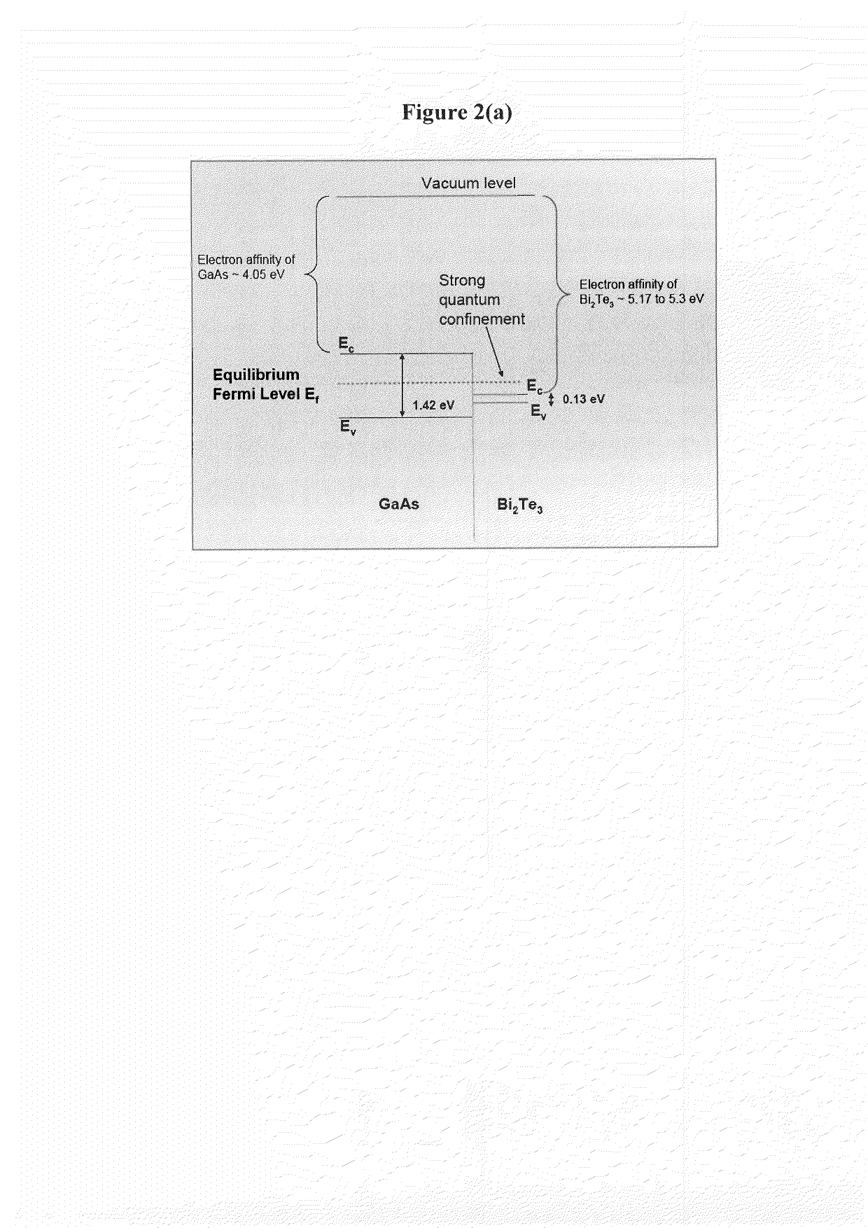

FIG. 2(a) is a schematic of the hetero-structure band diagram of n-type Bi₂Te₃ film with semi-insulating GaAs (E_{f} at mid-gap) on one side and free space on other side—with tailor-made structure for strong quantum confinement in n-type Bi₂Te₃. A quantum-confined Bi₂Te₃ structure according to one embodiment of the invention was achieved between semi-insulating GaAs and free-space, as shown in FIG. 2(a), where the details of the hetero-structure band diagram are shown. The electrically-insulating nature of the semi-insulating GaAs on one side of the Bi₂Te₃ film as well as the air on the other side, provides a potential-well, quantum confinement in ultra-thin mesoscopic layer of Bi₂Te₃. FIG. 2(b) is a schematic of a more general depiction of the Fermi levels and band energies of this invention.

While not limited to this explanation, the devices of the invention are considered to have a topological insulator (TI) behavior with “bulk” insulating or more correctly (semiconductor) conduction with conducting surface states which are topologically protected against scattering is expected to be active in ultra-thin Bi₂Te₃ films. A topological insulator is a material that behaves as an insulator in its interior while permitting the movement of charges on its boundary. In the bulk of a topological insulator the electronic band structure resembles an ordinary insulator, with the Fermi level falling between the conduction and valence bands. On the surface of a topological insulator, there are special states which fall within the bulk energy gap and allow extremely high conduction. As the Bi2Te3-film is thinned down, the “ordinary” bulk contributions get minimized, and the “surface state” contributions from the six surfaces of the Bi2Te3-film increase as a percentage of total conduction.

Essentially, the device structures of this invention can be considered to produce a near delta function in the density of states through the quantum confined by the barriers shown in FIGS. 2(a) and 2(b) over the relative short distance associated with the thickness of ultra-thin mesoscopic layer of Bi₂Te₃. The quantum confinement is considered to keep the Seebeck coefficient but use the large density of states to keep the number of carriers (n) large. By pinning the Fermi level and thinning the Bi₂Te₃ layer, the power factor can be raised as the thermal conductivity reduced by low-dimensional phonon-scattering effects [Ref 3, 27].

### Electron Transport Properties

The in-plane electrical transport of the ultra-thin Bi₂Te₃ films, from 2 nm to 58 nm, grown on semi-insulating GaAs substrates (resistivity of 1×10⁸ Ohm-cm) are amenable for measurement of in-plane electrical conductivity as well as in-plane Seebeck coefficient. One can measure the electrical conductivity of these Bi₂Te₃ films as well as their Seebeck coefficient. For comparison, a Bi₂Te₃ film ˜28 nm thickness was grown on an insulator (MgO). Quantum confinement effects or other mesoscopic effects are expected to be minimal for this thickness. Yet, nearly-identical in-plane electrical conductivity as in semi-insulating GaAs was observed.

The in-plane electrical resistivities of the Bi₂Te₃ thin-films were measured by the well-known van der Pauw method in a Hall-effect set up that measured both in-plane electrical resistivity and carrier mobility/concentration at 300K. The van der Pauw method, using four (4) very small contacts (compared to the size of sample) symmetrically on the four (4) corners of a typical square sample, ensures good measurement accuracy of the in-plane electrical resistivity.

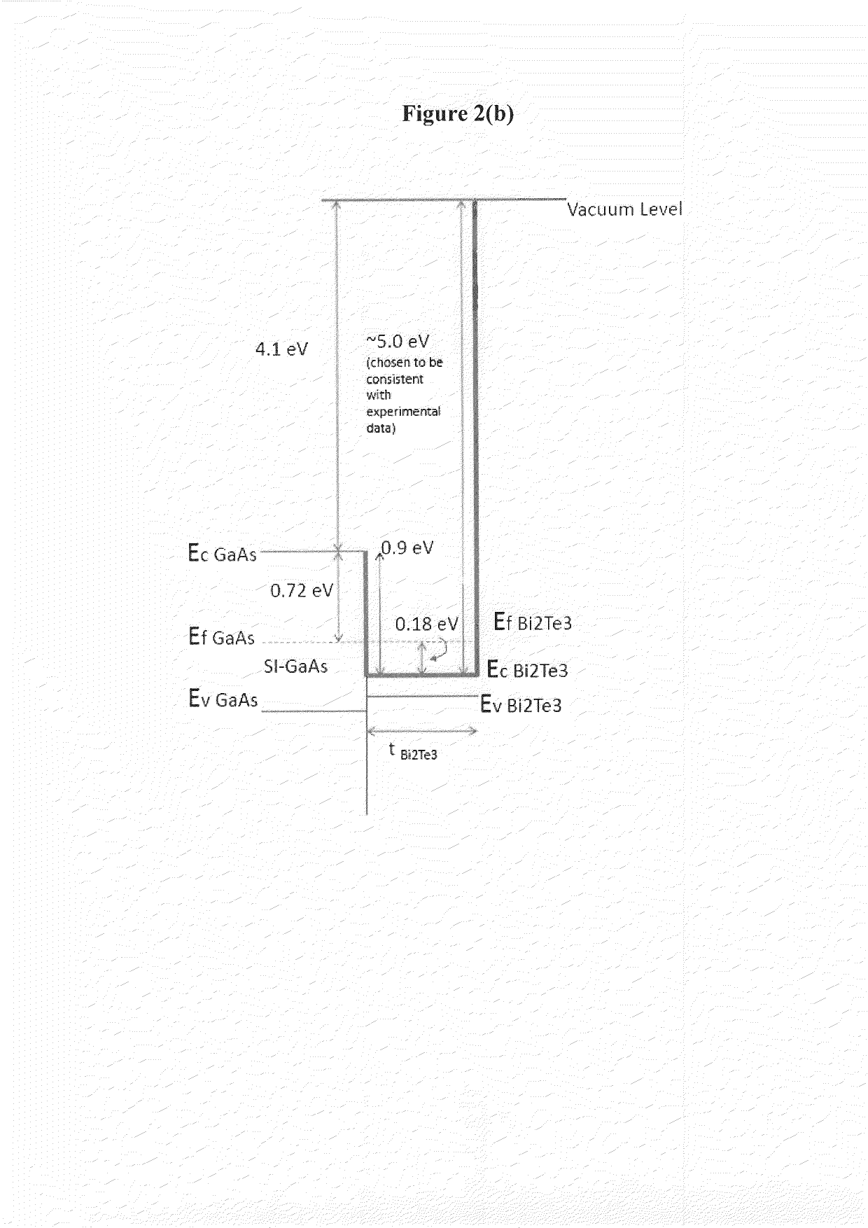

FIG. 3 shows electrical resistivity as a function of the film thickness. All the films were n-type and were measured at 300K. Note the choice of multiples of ˜30 Å x-axis scale, corresponding to the c-axis unit cell dimension of Bi₂Te₃ of ˜30 Å. The monotonic decrease in electrical resistivity as the film thickness is reduced from 58 nm to 2 nm, is seen from the data in FIG. 3. It is remarkable that as one moves from the 58 nm Bi₂Te₃-film that shows classical bulk-like electrical resistivity along the plane (a-b axis) of the film, towards thicknesses below 10 nm to 2 nm, the in-plane electrical conduction in Bi₂Te₃ semiconductor approaches metallic-like resistivities, being as low as 2.2×10⁻⁵ Ohm-cm for a 2 nm film. A 6 nm Bi₂Te₃ film shows an electrical resistivity of 6.33×10⁻⁵ Ohm-cm; the semi-insulating GaAs substrate that is 600 micron-thick has a typical resistivity of 10⁸ Ohm-cm. Thus the sheet conductance (thickness/resistivity) of the 6-nm-Bi₂Te₃ film is about 1.6×10⁷ times larger than that of any possible conduction of the semi-insulating GaAs substrate.

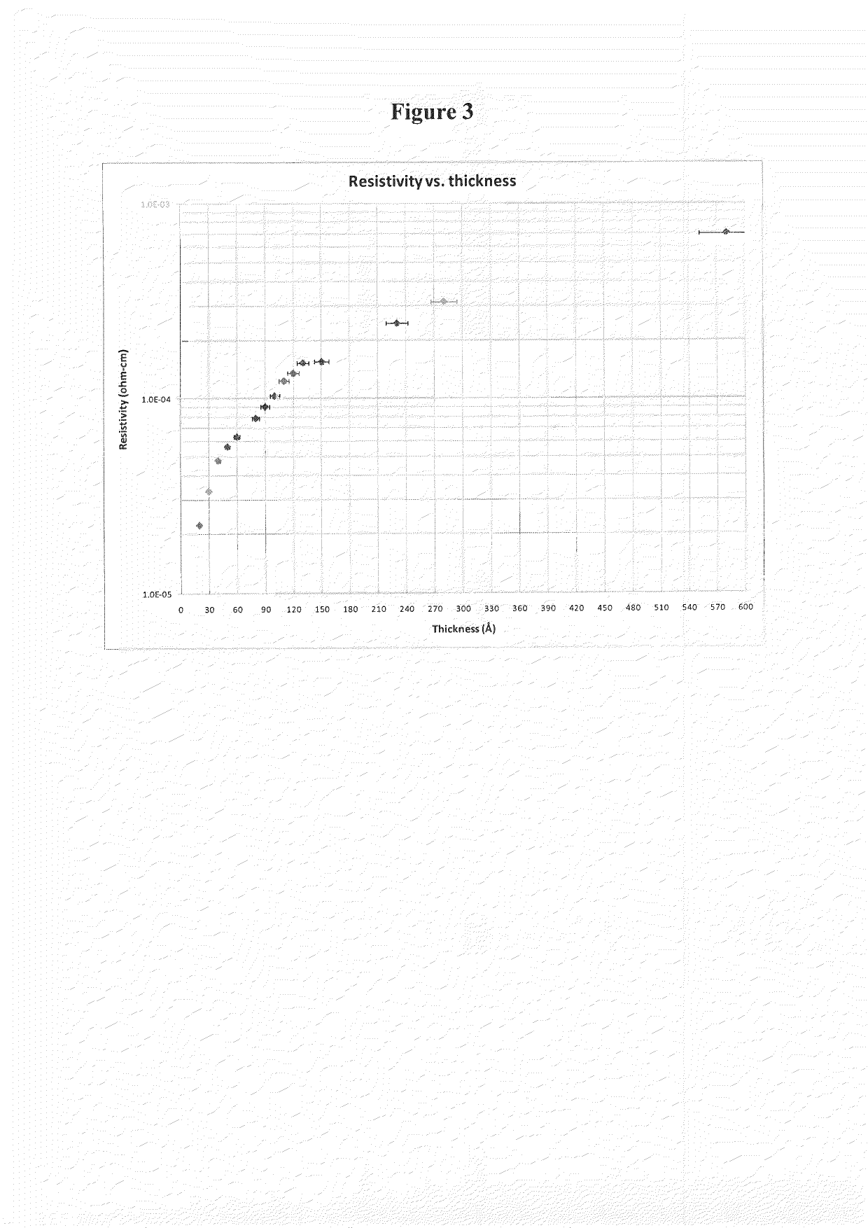

FIG. 4(a) is a schematic of in-plane Seebeck set-up, and FIG. 4 (b) shows measured absolute values of the in-plane Seebeck coefficient (α) at ˜300K of the ultra-thin n-Bi₂Te₃ films grown on semi-insulating GaAs plotted as a function of film thickness. Note the choice of multiples of ˜30 Å x-axis scale, corresponding to the c-axis unit cell dimension of Bi₂Te₃ of ˜30 Å. In other words, FIG. 4(a) shows the schematic of measurement set-up used for obtaining the Seebeck data of the ultra-thin Bi₂Te₃ films on semi-insulating GaAs. Similar to the above-described measurement of electrical transport, the in-plane Seebeck coefficient of the ultra-thin films could also be reliably obtained. Any surface states from the TI behavior and/or quantum-confined transport in the films that contribute to electrical transport are also part of the effective thermopower measurements. All the films showed negative Seebeck coefficient, consistent with n-type transport identified by Hall-effect. The absolute value of the Seebeck coefficient of the ultra-thin Bi₂Te₃ films, as a function of film thickness is shown in FIG. 4(b).

In contrast to the monotonic decrease in electrical conductivity as the film thickness is reduced (in FIG. 3), three features are observed—(a1) the Seebeck coefficient increases rapidly with low-dimensionality; (b1) the Seebeck coefficients show apparent minima or points of inflexion at multiples of unit cell thicknesses, namely, 30, 60, 90 and 120 Å; and (c1) the Seebeck coefficients are rather large for the concomitant electrical conductivities in films with ultra-low thickness values compared to bulk Bi₂Te₃ materials.

While the present invention is not so limited, these features suggest several possible mechanisms working separately or in tandem—(a2) Quantum-confinement (from FIG. 2) leading to enhanced density of states, (b2) perhaps TI behavior, rather the presence of a strong surface state and dissipation-less conduction, and (c2) a large electronic transport conductance which is unlike in metallic conduction or degenerate semiconductors due to the considerable shift in electronic band energies from the conduction band minima, as depicted in FIG. 2, with a sharp density of states.

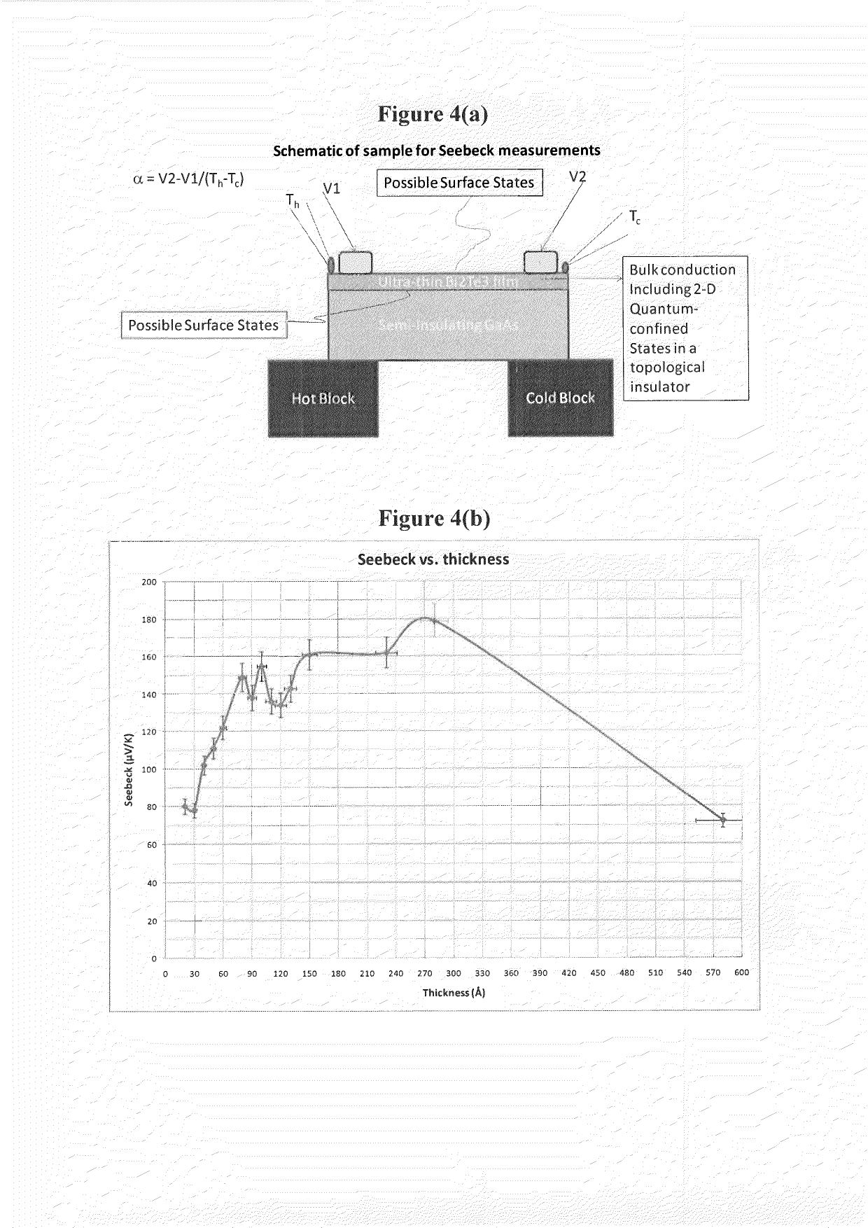

The strong enhancement in electrical conductivity and the simultaneous presence of appreciable thermopower in the ultra-thin-Bi₂Te₃ films, as thickness is reduced, leads to a rather large increase in thermoelectric power factor (α²σ) as shown in FIG. 5. FIG. 5 shows measured in-plane thermoelectric power factor (α²σ) at ˜300K as a function of thickness of the Bi₂Te₃-film thickness; note the apparent minima or points of inflexion at ˜30 Å, 60 Å, 90 Å, 120 Å. The effect of the square-dependence of the Seebeck coefficient accentuates the previously noted minima or points of inflexion in the in-plane power factor data at ˜30 Å, 60 Å, 90 Å, 120 Å, respectively. This complex power factor behavior as a function of thickness arises from multiple effects, through various scattering (or absence of scattering) in ultra-thin Bi₂Te₃ films. In any case, the factor of seven (7) increase in thermoelectric power factor (˜280 μW/K²-cm) over that obtainable in bulk Bi₂Te₃ and its alloys at 300K, and being able to obtain this large enhancement at ˜80 Å of Bi₂Te₃ CVD film without the need for ˜7.8 Å-single-quintuple-layer shows one of the novel aspects of the invention.

### Thermal Transport Properties

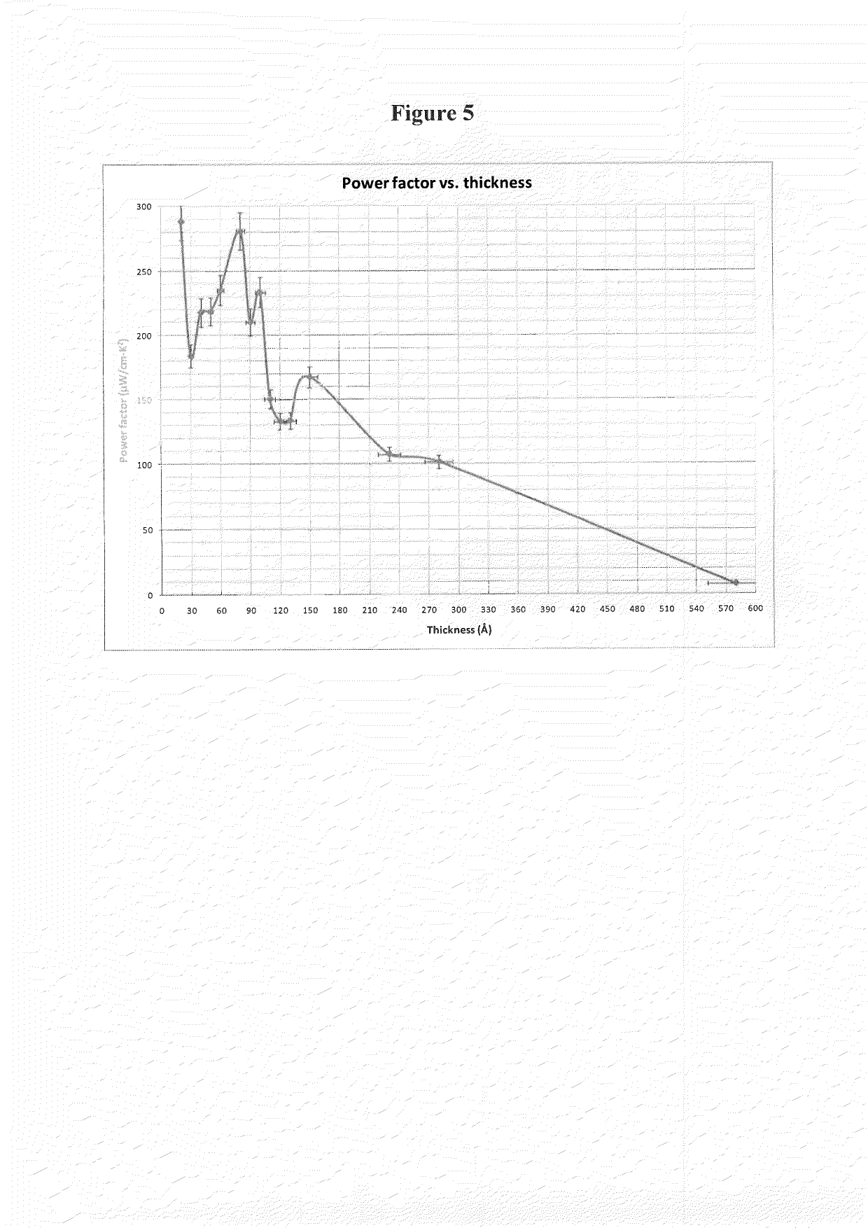

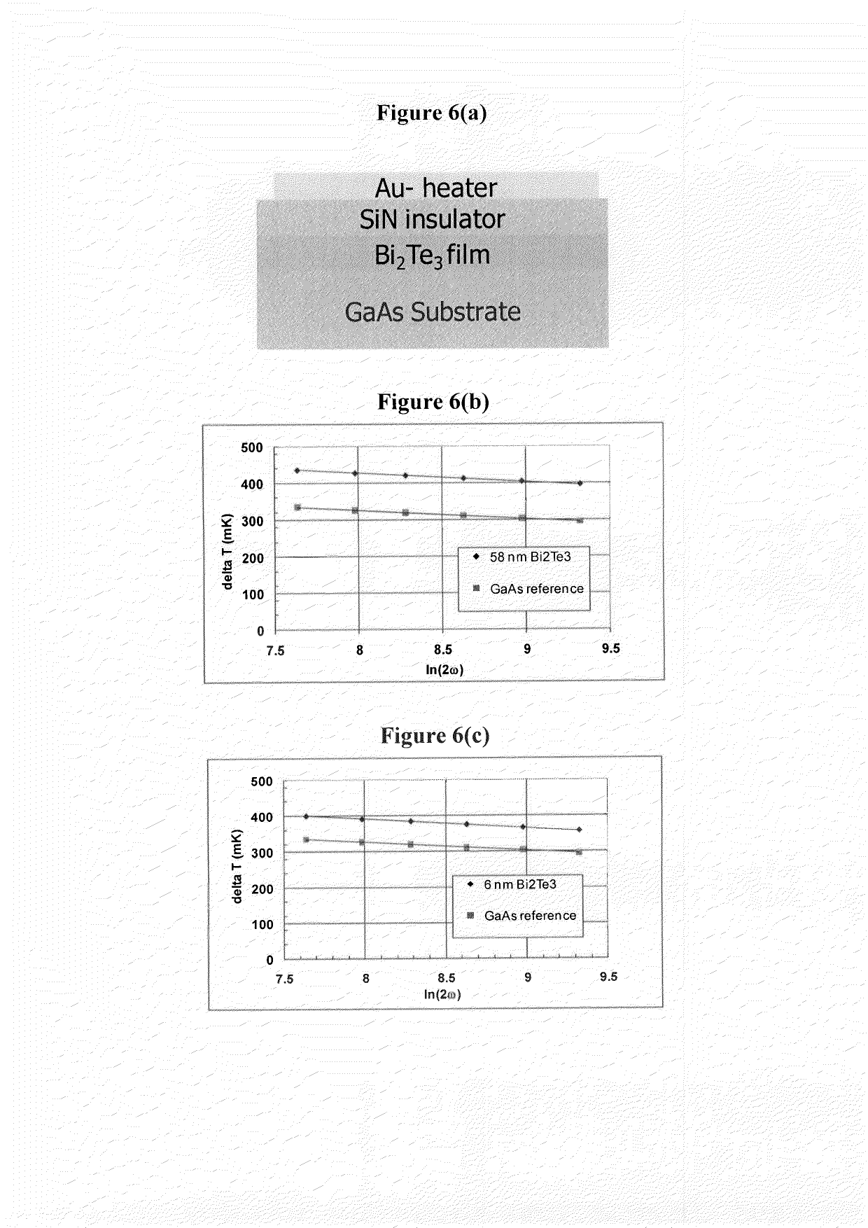

While the in-plane electrical transport of the ultra-thin Bi₂Te₃ films can be reliably studied, the measurement of in-plane thermal transport is more difficult due to the unavoidable thermal shunt of the GaAs substrate. However, the characterization of cross-plane thermal transport of ultra-thin films can be achieved using the 3-ω method. FIG. 6(a) is a cross-sectional schematic of structure used for 3ω-measurement; FIG. 6(b) is a graph opf ΔT vs in (2ω) for the GaAs/SiN reference and the GaAs/Bi₂Te₃(58 nm)/SiN structure; FIG. 6(c) is a graph of ΔT vs in (2ω) for the GaAs/SiN reference and the GaAs/Bi₂Te₃(6 nm)/SiN structure In other words, FIG. 6 shows the schematic of cross-plane thermal conductivity structures and the typical ΔT vs ln(2ω) for two samples (6 nm and 58 nm Bi₂Te₃). The thermal resistance of the SiN isolation layer is accounted with a 3ω measurement on a reference GaAs substrate, also with the same thickness SiN done at the same time. From the ΔT difference between the two structures carried out as a function of frequency, along with the power input to the heater normalized per unit length and thickness of the Bi₂Te₃ film, the thermal conductivity in the cross-plane direction can be determined. FIG. 7 shows the cross-plane thermal conductivity as a function of Bi₂Te₃ film thickness, measured by the 3-ω method. The thermal conductivity shows an inverse dependence on thickness, interestingly, down to 28 to 4 nm scales. The thermal conductivity λ(I), of a structure of thickness I, along the direction of thickness, can be written as follows

(1/λ)(l))=(1/λ_{bulk})+(a/l) (1)

where λ_{bulk} is thermal conductivity of the bulk material and a is a size-independent constant.

For ultra-thin materials, when (a/l)>>(1/λ_{bulk}), one expects a near-linear relationship between measured thermal conductivity and size l, as seen in FIG. 7. As l increases past ˜28 nm, the size-dependent factors become less influential and time constants associated with bulk thermal conductivity processes take over, and overall thermal conductivity is smaller than that extrapolated from size-effects. The extremely low thermal conductivities (<0.1 W/m-K) measured for thicknesses less than 100 Å of crystalline Bi₂Te₃ are unprecedented. These total thermal conductivities are a factor of two and a half (2.5) times smaller than lowest reported lattice thermal conductivities in Bi₂Te₃-based superlattices, a factor of ten (10) times smaller than total thermal conductivity observed in high ZT (˜2.4) Bi₂Te₃/Sb₂Te₃ superlattices, and more than a factor of seventeen (17) times smaller than total thermal conductivity observed in commercial Bi₂Te₃-alloy (ZT˜1) materials.

The large in-plane electrical conductivity and power factor seen in these ultra-thin Bi₂Te₃ materials are retained after SiN deposition (at 175° C.) and 3-ω measurements of thermal conductivity. For example, the 6-nm-Bi₂Te₃ film showed a power factor 235±12 μW/cm-K² as grown and 220±11 μW/cm-K² after SiN deposition, indicating that the quantum-confinement and/or TI behavior is robust and can withstand standard device processing sequences.

Implications for Figure of Merit (ZT)

The seven-times increase in power factor in the in-plane direction and more than a factor of seventeen (17) decrease in thermal conductivity in the ultra-thin Bi₂Te₃ films, compared to standard Bi₂Te₃-alloy materials, will have a dramatic impact on ZT of these materials. The nature of the observed enhancement in power factor is due to a complex set of processes, ranging from strong quantum-confinement (FIG. 2) at the GaAs/Bi₂Te₃/air interface and also potential topological surface-state conduction. While the invention is not so limited, several scenarios for ZT enhancement in these ultra-thin Bi₂Te₃ films with the observed unusual thermal and electrical transport properties are described below for the purposes of explanation.

First, given that these films exhibit vanishing lattice thermal conductivities (for thicknesses<100 Å), the Seebeck coefficient and Lorentz number are expected to be isotropic and therefore the ZT is also expected to be isotropic. One can estimate the worst-case electrical conductivity anisotropy as a function of measured in-plane electrical conductivity of n-Bi₂Te₃ from the 3-decades of observed data with the measured anisotropy (A) in electrical conductivities, defined as

A=ρ_{c}/ρa−b=σ_{a-b}/σ_{c} (2)

where ρ_{c} and ρ_{a-b} represent the electrical resistivities along the c-axis direction or direction along the periodic van der Waal planes in Bi₂Te₃ and in the a-b plane, respectively, and σ, is electrical conductivity.

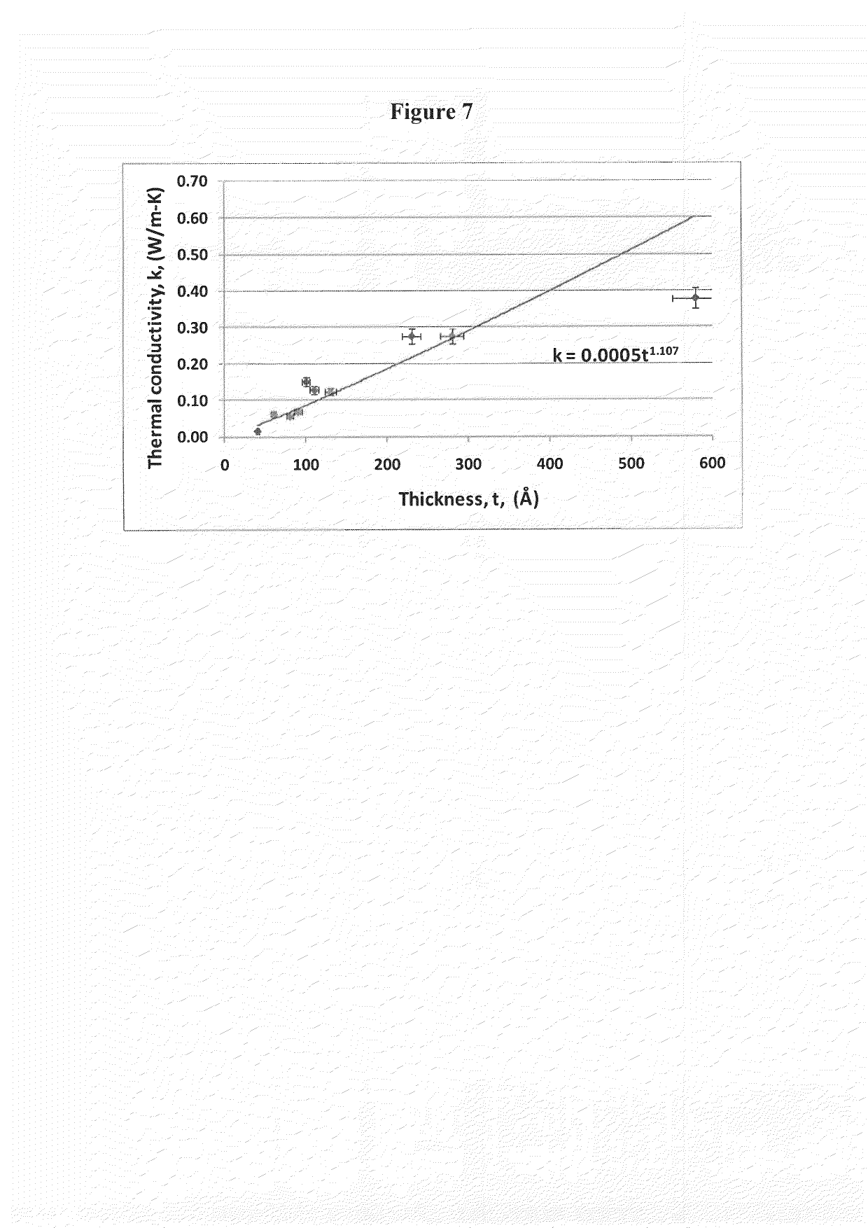

σ_{a-b} and σ_{c} are also often referred to as σ₁₁ and σ₃₃, respectively. A is in the range of 4 to ˜6, implying cross-plane electrical conductivity is 4 to 6 smaller than the in-plane electrical conductivity (FIG. 8a). More specifically, FIG. 8(a) is a graph of the anisotropy of electrical conductivity, or the factor by which cross-plane electrical conductivity is lowered, as a function of in-plane electrical conductivity in n-type Bi₂Te₃ denoted as S₁₁. The anisotropy increase with carrier concentration and/or electrical conductivity arises from the variation of the shape of the equi-energy surfaces from perfectly ellipsoidal, in momentum space. Given that the ultra-thin Bi₂Te₃ films described here are much more conductive than previous materials considered, a model in the extrapolation of anisotropy to higher electrical conductivities utilized a simpler linear model and an exponential model, consistent with energy-dependent carrier scattering time constant. The two modeling parameters from the curve fit, shown in FIG. 8(a), were applied to estimate the anisotropy as a function of Bi₂Te₃ film thickness as shown in FIG. 8(b) from their respective measured in-plane electrical conductivity in FIG. 3. More specifically, FIG. 8(b) is a graph of the anisotropy of electrical conductivity or the factor by which cross-plane electrical conductivity is lowered as a function of thickness of the ultra-thin Bi2Te3 films in this invention, using the above two exponential and linear trends.

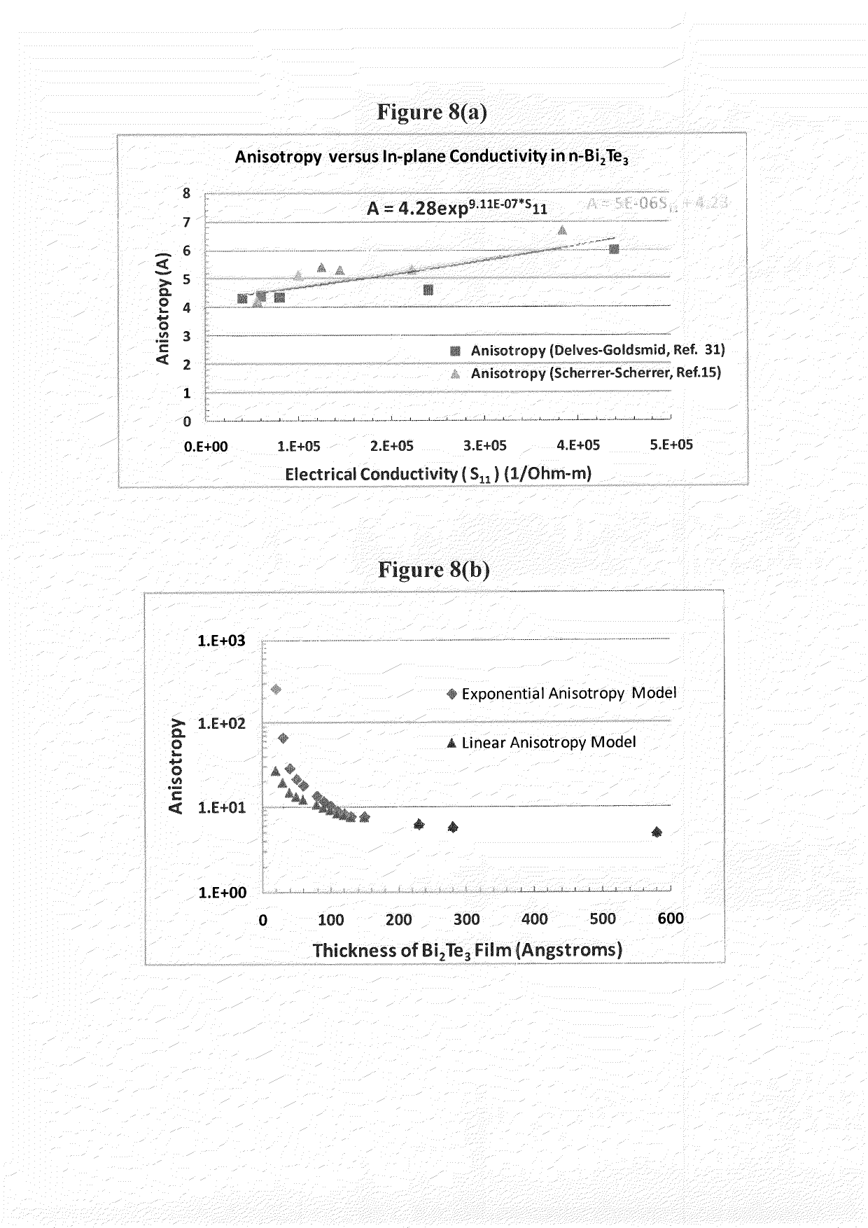

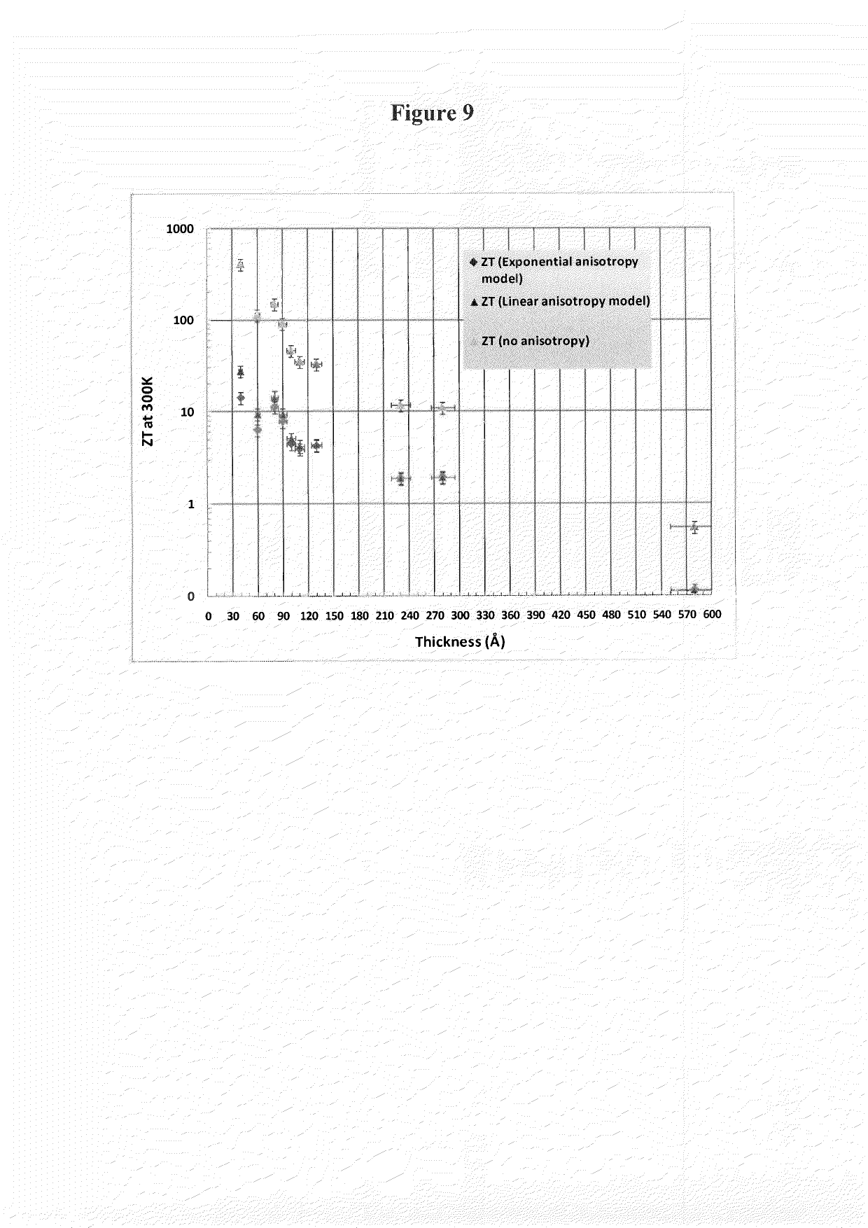

Once the anisotropy is determined as a function of thickness, and since thermal conductivity in the cross-plane is known and since the Seebeck coefficient is isotropic, ZT can be estimated as a function of film thickness. FIG. 9 shows the estimated ZT at 300K as a function of film thickness (for the two anisotropy models) of ultra-thin Bi₂Te₃ films, using the above two exponential and linear trends for anisotropy and also for absence of anisotropy. FIG. 10 is a depiction of the effective Lorentz Parameter from the measured thermal conductivity and the estimated electrical conductivity, for the two anisotropy models

It is surprising and unexpected to note that the ZT can approach 10 and exceed 10 for film thickness as large as 90 Å. For film thickness of ˜40 Å the ZT is between 14 and 28 and for ˜80 Å film, the ZT is between 11 and 14. Further that the ZT estimated for a 60 Å, corresponding to two complete unit-cell thickness, is relatively smaller between 6 and 9. Thus, the observed behavior in ZT enhancement is not a straightforward combination from low-dimensional effects, quantum-confinement effects and topological insulator effects. The quantized nature of electrical transport in the GaAs/Bi₂Te/air heterostructure as well as potential topological state conduction would also suggest that anisotropy is non-existent in this electronic conduction system. Further, the anisotropy increase is based on the assumption of acoustic mode lattice scattering that is present in highly conducting samples in bulk N-Bi₂Te₃, may be weak or absent in ultra-thin N-Bi₂Te₃ films where the inventors have observed vanishing lattice thermal conductivity. FIG. 9 shows the potential ZT in ultra-thin Bi₂Te₃ films if the anisotropy is absent one and shows that the ZT values for the 90-to-40-Å films are in excess of 100.

The extraordinarily low measured thermal conductivities in the ultra-thin Bi₂Te₃ films while simultaneously exhibiting high electrical conductivities, notwithstanding the correction for anisotropies, leads to anomalously low Lorentz parameter. These are shown in FIG. 10, for the two cases of anisotropy models. For the 580 Å film, with the expected lattice thermal conductivity of 0.17 W/m-K¹⁶, from the measured cross-plane thermal conductivity and with either anisotropy model for electronic conductivity, a Lorentz parameter (Lₒ) is calculated to be in the range of 2.33 to 2.37E-8 V²/K², in excellent agreement with the standard model for near-degenerate and bulk-like electronic conduction. However, the remarkable drop in effective Lₒ with low-dimension, with either anisotropy model, is seen. This may be one of the first experimental demonstrations of a reduction in Lₒ in mesoscopic, non-metallic, electronic systems. If the anisotropies were to be absent in electronic conduction, then, the decrease in Lₒ would be even more substantial.

The anomalous behavior of ultra-large electrical conductivity in the ultra-thin Bi₂Te₃ films, with diminishingly small thermal conductivity, is reminiscent of weakly superconducting-like behavior. The possibility of large electrical conductivity, with extremely small thermal conductivity, suggests that the electrical transport in the ultra-thin Bi₂Te₃ films occurs in a fairly orderly state such as in a condensate. Since heat transport is also associated with disorder or entropy, similar to the superconducting state which is one of near-perfect order and so there is minimal entropy to transport and therefore no thermal conductivity, the weak electron-electron condensate in ultra-thin-Bi₂Te₃ films, for thickness in the range of and below 100 Å, could be the source of such observations.

Excitonic condensate, as opposed to an electron-electron condensate may be possible in these n-type ultra-thin Bi₂Te₃ films, in a topological insulator such as Bi₂Te₃ described here. While “weak” electron-electron condensate systems may not have all the attendant advantages of excitonic condensate systems, being made up of charged particles as opposed to a neutral excitonic particle, such system could still offer “valuable” thermoelectric Seebeck coefficient. In any case, the observed large electrical conductivity in the in-plane and ultra-low thermal conductivity in cross-plane suggests an unusual electronic transport system in ultra-thin Bi₂Te₃ films.

In summary, the inventors have observed unusual and highly advantageous thermoelectric characteristics of ultra-thin Bi₂Te₃ films in the range of 2 nm to 58 nm grown on electrically-insulating GaAs substrates. The films at the thinner dimensions show ultra-high electrical conductivity, yet show sufficiently large Seebeck coefficient leading to a major enhancement in power factor, almost a factor of seven (7) times larger than typical bulk Bi₂Te₃ materials.

The enhancement in power factor as a function of film dimension suggests that this result could be a combination of quantum-confinement effects as well as topological insulator or a condensate behavior. The Bi₂Te₃ films near the thinner dimensions, show ultra-low thermal conductivities as measured by 3-ω method. The measured thermal conductivities in such ultra-thin mesoscopic films, with potential combination of quantum confinement and topological insulator effects, appear to be at significant deviation from the well-known Wiedemann-Franz law.

The large enhancement in power factor with the ultra-low thermal conductivities could potentially lead to thermoelectric figure of merit ZT the range of 14 to 28 at 300K, when corrected for potential anisotropy of thermal conductivities, to over 400 at 300K, if anisotropies do not exist in these novel electronic conduction systems, in such n-type Bi₂Te₃ thin films.

The results of this invention appear to present a fundamentally different approach in thermoelectric material design for high-efficiency solid state thermal-to-electric energy conversion. From a device implementation perspective, for advanced thermoelectric devices for electronics cooling to energy harvesting, these results provide novel device designs.

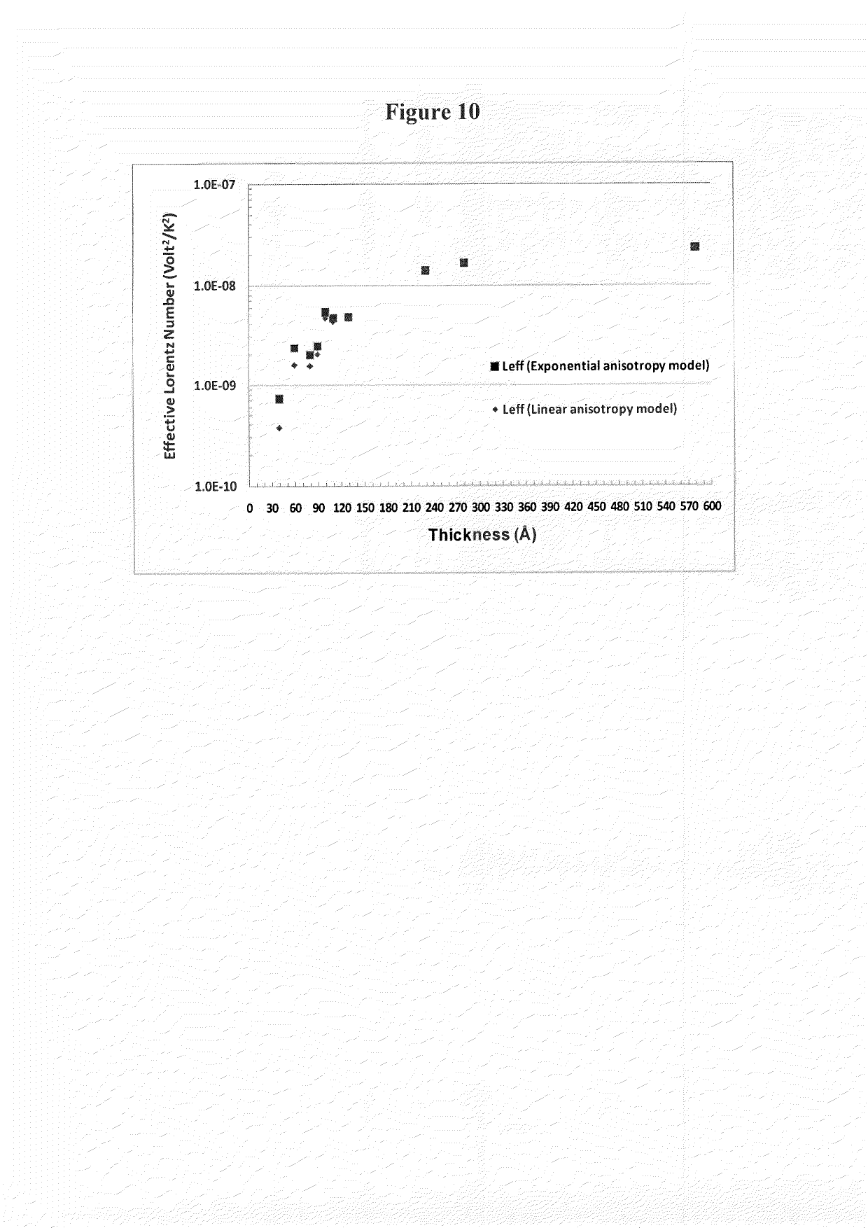

FIG. 11 is a schematic of thermoelectric generator according to one embodiment of the invention. The thermoelectric generator 10 includes a thermoelectric structure including a thermoelectric material 12 having a thickness less than 50 nm and a semi-insulating material 14 in electrical contact with the thermoelectric material. The thermoelectric material and the semi-insulating materials have respective electron affinities such that an equilibrium Fermi level across a junction between the thermoelectric material and the semi-insulating material exists in a conduction band or a valence band of the thermoelectric material. In the thermoelectric generator 10, a heat spreader 16 is connected to a first longitudinal end of the thermoelectric material 12, and a heat sink 18 is connected to a second longitudinal end of the thermoelectric material 12. Upon establishing a temperature differential between the heat spreader and the heat sink (such as for example by supplying heat to the heat spreader from a waste heat source, a voltage potential develops across the first and second longitudinal ends of the thermoelectric material 12. As shown in FIG. 11, there are multiple thermoelectric structures connected as n- and p-type thermoelectric sections. Heat sink 18 is shown segmented to permit electrical conduction separately through each of the n- and p-type thermoelectric pairs.

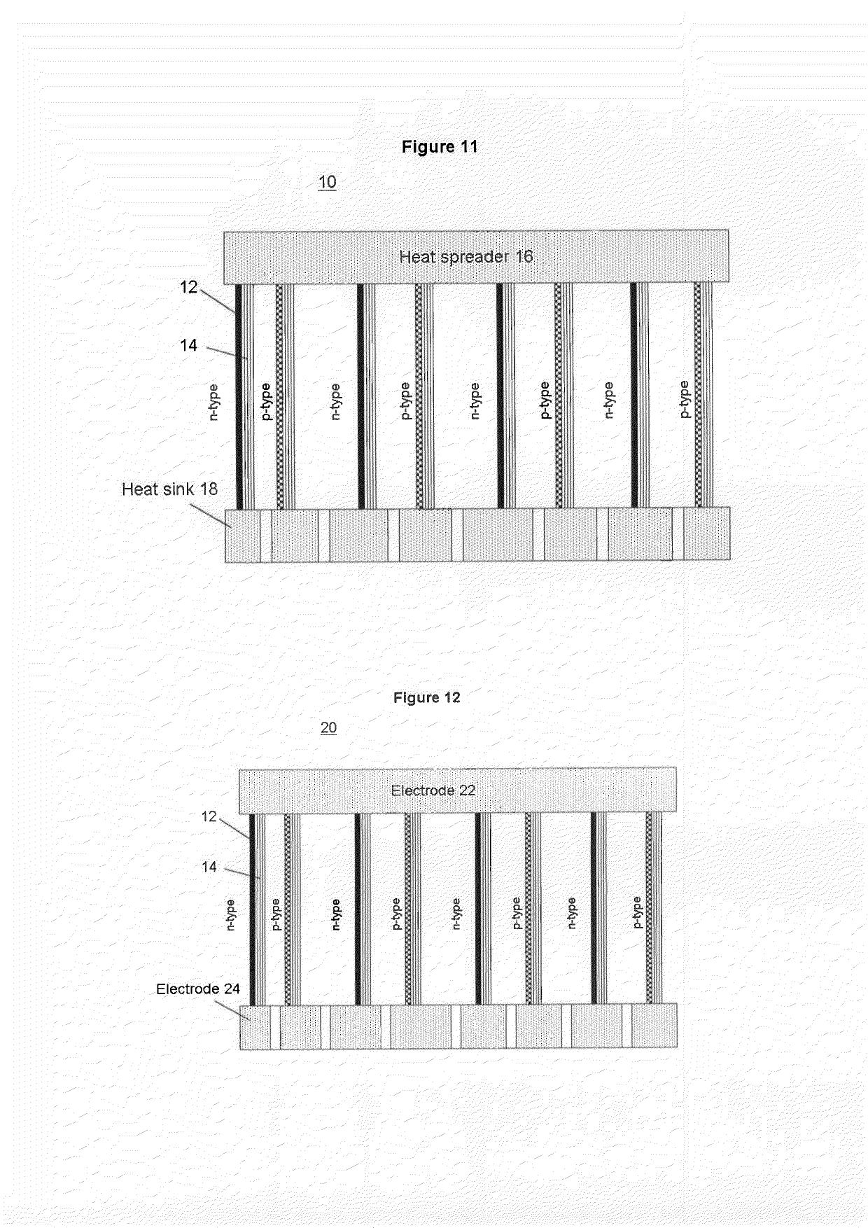

FIG. 12 is a schematic of a thermoelectric cooler 20 according to one embodiment of the invention. The thermoelectric cooler 20 includes (similar to the thermoelectric generator 10) a thermoelectric structure including a thermoelectric material 12 having a thickness less than 50 nm and a semi-insulating material 14 in electrical contact with the thermoelectric material. As above, the thermoelectric material and the semi-insulating materials have respective electron affinities such that an equilibrium Fermi level across a junction between the thermoelectric material and the semi-insulating material exists in a conduction band or a valence band of the thermoelectric material. In the thermoelectric cooler 20, a first electrode 22 is connected to a first longitudinal end of the thermoelectric material 14, and a second electrode 24 is connected to a second longitudinal end of the thermoelectric material 14. Upon carrier conduction through the thermoelectric material such as by application of an electric potential to electrically flowing current through a n-type thermoelectric material, the first stage, and a p-type material, a temperature differential develops across the first and second stages to cool the first stage relative to the second stage. As shown in FIG. 12, there are multiple thermoelectric structures connected as n- and p-type thermoelectric sections. Electrode 24 is shown segmented to permit electrical conduction separately through each of the n- and p-type thermoelectric pairs.

Thin-Film Device Fabrication Sequence:

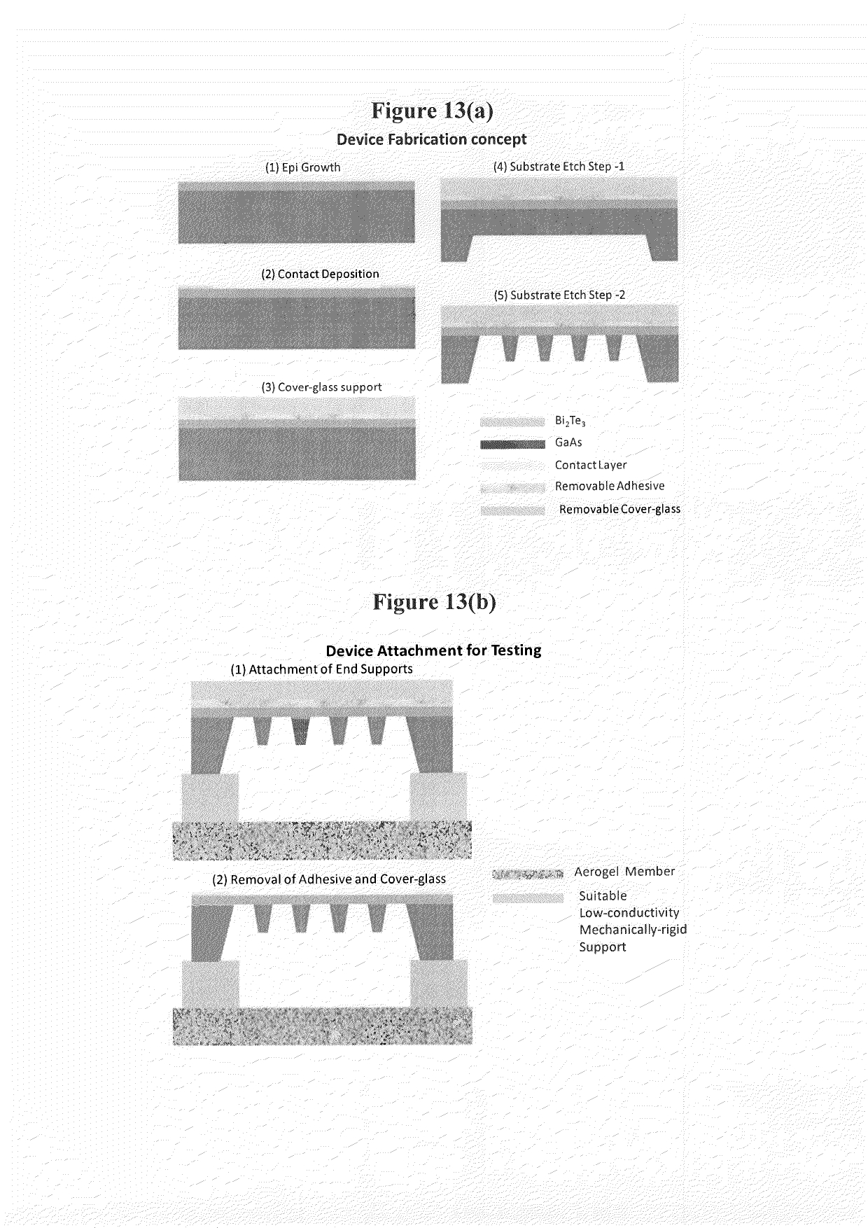

FIG. 13a is a schematic showing a sequence according to this invention for device fabrication with ultra-thin Bi₂Te₃ films. The first step includes the thin Bi₂Te₃ epi (˜10 nm) growth on semi-insulating GaAs substrate, followed by the second step of a suitable contact deposition. The contacts, for low specific contact resistivities to n-GaAs, include Cr/Ti/Cu/Au where we can obtain contact resistivities in the range of 10⁻⁷ Ohm-cm², especially at carrier concentration levels of several 10¹⁹ cm⁻³ and higher. The contact deposition is followed by attachment of a cover-glass support using a dissolvable adhesive (like photoresist) in step 3. Following the attachment of cover-glass support, in step (4), a partial substrate removal etch of about 500 microns (about 80% of the thickness of the GaAs substrate) is carried out. The GaAs substrate can be removed by an etch consisting of 1:1:10=H₂O₂:NH₄OH:H₂O rather rapidly at about 5 μm/min. In step (5), another substrate etch is carried out, that is slower and more selective so that the etch completely stops at the Bi₂Te₃ surface, to create supporting GaAs ribs while achieving complete isolation of the ultra-thin Bi₂Te₃ in several segmented regions as shown in FIG. 13a, Step (5). The number of GaAs ribs that need to be provided will be optimized through empirical observation.

FIG. 13b is a schematic of a process sequence to attach a processed device structure to a suitable, low thermal conductivity, mechanically rigid support structure. More specifically, FIG. 13b is a schematic of sequence taking processed device structures in FIG. 4a and removing the cover-glass and adhesive for various device-level applications. The rigid support is in turn mounted on an aerogel connecting member. Once the attachment of supports are done, the adhesive is dissolved and the cover-glass taken out.

The above description is one embodiment of a device application of the advantageous ultra-thin-Bi2Te3-films for thermoelectric applications. But other embodiments utilize the deposition of ultra-thin-Bi2Te3 films on a CaF₂ layer and/or others insulators on a Si substrate, where the devices of this invention can be integrated with Si-electronics, including those compatible with Si-CMOS circuitry. In such situations, it may not be necessary to remove the substrate on which the ultra-high-ZT Bi₂Te₃-films are deposited by growth methods such as MOCVD, thermal evaporation, MBE, etc.

Device-Level Cooling:

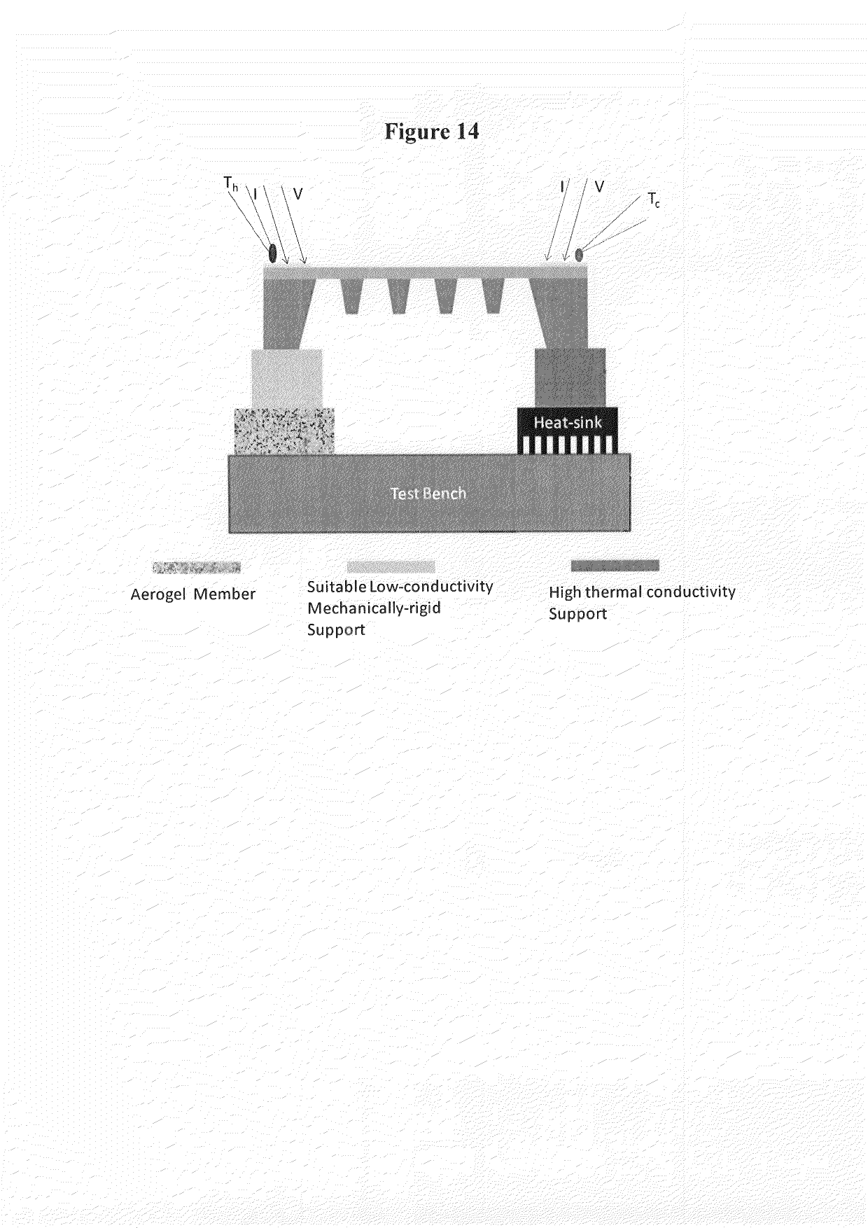

FIG. 14 is a schematic showing a cooling device of this invention using the ultra-thin Bi₂Te₃ films and structures noted above. More specifically, FIG. 14 is a schematic of use of the thin-film planar device structures for cooling and heat extraction. The structure is a variant of the structures shown in FIGS. 13a and 13b. For large-aspect ratio devices, defined as length/area of the thermoelectric element, in-plane device should be able to achieve a ΔTₘₐₓ to be reached at currents of <100 mA. This arrangement, according to one embodiment of this invention, provides significant advantages for spot-cooling of infra-red focal plane array elements. Additionally, in one embodiment of this invention, infra-red focal plane arrays with micro-cryogenic cooling would benefit from these advanced ultra-thin thermoelectric material structures. In one embodiment of this invention, electronics cooling, where needed, would also benefit from these device level cooling structures.

Device-Level Heat-to-Electric Power:

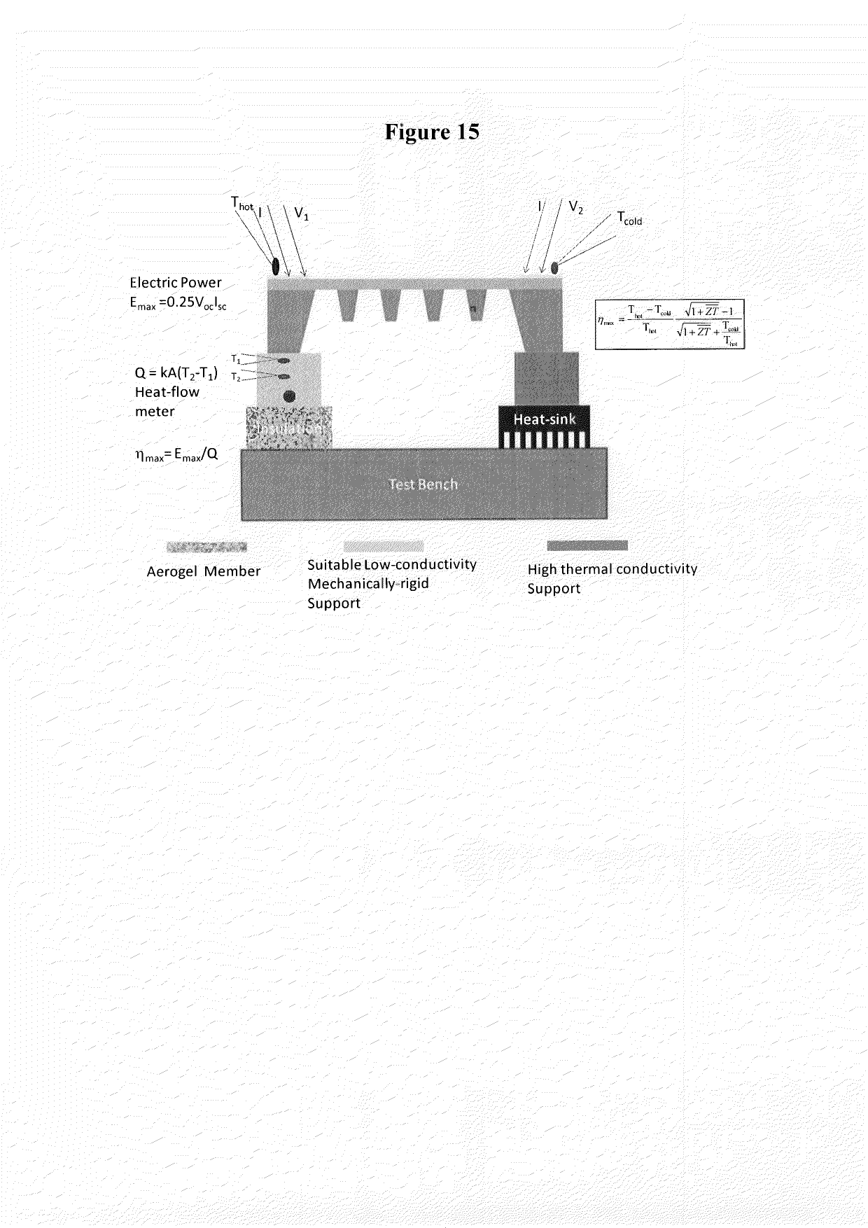

FIG. 15 is a schematic of a thin-film planar device structure for heat-to-electric power conversion using the ultra-thin Bi₂Te₃ films and structures noted above. The structure is a variant of the structures shown in FIGS. 13a and 13b and 14. In one embodiment of this invention, these structures are utilized for efficient energy harvesting and/or to produce useful voltages for connecting to electronic loads. In one embodiment of this invention, these heat harvesting power devices are integrated with Si, GaAs, GaN, InP microelectronic chips that generate a significant amount of heat both on the front-side and back-side.

Numerous modifications and variations of the invention are possible in light of the above teachings. It is therefore to be understood that within the scope of the appended claims, the invention may be practiced otherwise than as specifically described herein.

1. A thermoelectric structure comprising:
a thermoelectric material having a thickness less than 50 nm;
a semi-insulating material in electrical contact with the thermoelectric material;
said thermoelectric material and said semi-insulating materials having an equilibrium Fermi level, across a junction between the thermoelectric material and the semi-insulating material, which exists in a conduction band or a valence band of the thermoelectric material.

2. The structure of claim 1, wherein the thermoelectric material is n-type crystalline Bi₂Te₃ and the semi-insulating material is GaAs.

3. The structure of claim 1, wherein the thermoelectric material is p-type crystalline Bi₂Te₃ and the semi-insulating material is GaAs.

4. The structure of claim 1, wherein the thermoelectric material comprises at least one of Bi₂Te₃, Sb₂Te₃, Bi₂Se₃, Bi₂₋ₓSbₓTe₃, and Bi₂Te₃₋ₓSeₓ.

5. The structure of claim 1, wherein the thickness of the thermoelectric material is less than 20 nm.

6. The structure of claim 1, wherein the thickness of the thermoelectric material is less than 10 nm.

7. The structure of claim 1, wherein the thermoelectric material has an electrical resistivity less than 6×10⁻⁵ ohm-cm.

8. The structure of claim 1, wherein the thermoelectric material has an electric resistivity less than 2×10⁻⁵ ohm-cm.

9. The structure of claim 1, wherein the thermoelectric material has a thermal conductivity less than 0.3 W/m-k.

10. The structure of claim 1, wherein the thermoelectric material has a thermal conductivity less than 0.1 W/m-k.

11. The structure of claim 1, wherein the thermoelectric material has a figure of merit ZT between 3 and 10 at 300K.

12. The structure of claim 1, wherein the thermoelectric material has a figure of merit ZT between 10 and 50 at 300K

13. The structure of claim 1, wherein the thermoelectric material has a figure of merit ZT between 50 and 100 at 300K.

14. The structure of claim 1, wherein the thermoelectric material has a figure of merit ZT between 100 and 500 at 300K.

15. The structure of claim 1, further comprising:
a heat source connected to a first longitudinal end of the thermoelectric material; and
a heat sink connected to a second longitudinal end of the thermoelectric material, wherein
upon establishing a temperature differential between the heat source and the heat sink, a voltage potential develops across the first and second longitudinal ends.

16. The structure of claim 1, further comprising:
a first temperature-controllable stage connected to a first longitudinal end of the thermoelectric material; and
a second temperature-controllable stage connected to a second longitudinal end of the thermoelectric material, wherein
upon carrier conduction through the thermoelectric material, a temperature differential develops across the first and second temperature-controllable stages.

17. The structure of claim 1, wherein said semi-insulating material comprises substrates of at least one of GaAs, InP, CdTe, or MgO.

18. The structure of claim 1, wherein the substrates have a crystallographic surface orientation of <100>, <111>, and surface orientations off-axis from the <100> and <111> orientations.

19. The structure of claim 1, wherein said semi-insulating material comprises a thinned semi-insulating substrate.

20. The structure of claim 19, wherein the thinned semi-insulating substrate is disposed on a low thermal conductivity material.

21. A thermoelectric structure comprising:
a thermoelectric material having a thickness less than 50 nm;
a semi-insulating material in electrical contact with the thermoelectric material;
said thermoelectric material having a figure of merit ZT between 3 and 10 at 300K.

22. The structure of claim 21, wherein the thermoelectric material has a figure of merit ZT between 10 and 50 at 300K

23. The structure of claim 21, wherein the thermoelectric material has a figure of merit ZT between 50 and 100 at 300K.

24. The structure of claim 21, wherein the thermoelectric material has a figure of merit ZT between 100 and 500 at 300K.

25. A method for generating thermoelectric power, comprising:
providing a heat source and a heat sink at a lower temperature than the heat source;
connecting at least one of an n-type thermoelectric material and a p-type thermoelectric material, having a thickness less than 50 nm and disposed on a first semi-insulating material, between the heat source and the heat sink; and
separately collecting carrier flow from the n-type thermoelectric material and carrier flow from the p-type material to form a thermoelectric potential related to a temperature differential between the heat source and the heat sink.

26. A method for thermoelectric cooling, comprising:
connecting at least one of an n-type thermoelectric material and a p-type thermoelectric material, having a thickness less than 50 nm and disposed on a first semi-insulating material, to a first temperature-controllable stage; and
electrically flowing current through the n-type thermoelectric material, the first temperature-controllable stage, and the p-type material to cool the first temperature-controllable stage relative to the second temperature-controllable stage.
